(19) United States
(12) Patent Application Publication
(10) Pub. No.: US 2026/0279414 A1
(43) Pub. Date: Sep. 17, 2026

(54) SELECTIVE SOURCE BIAS IN MEMORY PERIPHERY

(71) Applicant: SILVACO Inc., Santa Clara, CA (US)

(72) Inventor: Eitan Zmora, Mevaseret-Zion (IL)

(73) Assignee: SILVACO Inc., Santa Clara, CA (US)

(21) Appl. No.: 19/470,670

(22) PCT Filed: Apr. 1, 2024
(86) PCT No.: PCT/US2024/022514

§ 371 Date: Sep. 29, 2025

Related U.S. Application Data
(60) Provisional application No. 63/493,304, filed on Mar. 30, 2023.

(51) Int. Cl. G11C 5/14; G11C 11/4074; G11C 11/417

(52) U.S. Cl. CPC G11C 5/14; G11C 11/4074; G11C 11/417

(57) ABSTRACT

Technologies and implementations for a selective source bias for memory periphery. The selective source bias may be configured to minimize leakage, which in turn may lead to savings. The selective source bias may be configured to bias an off transistor.

### CROSS-REFERENCE TO RELATED APPLICATIONS

This application claims benefit of priority to U.S. Provisional Patent Application Ser. No. 63/493,304, filed on Mar. 30, 2023, titled SELECTIVE SOURCE BIAS IN MEMORY PERIPHERY, which is incorporated herein by reference in its entirety for all purposes.

### INFORMATION

Unless otherwise indicated herein, the approaches described in this section are not prior art to the claims in this application and are not admitted to be prior art by inclusion in this section.

Memory cell arrays may have applicability in many digital technologies. A variety of types of memory may be utilized in digital technologies. Some memory types may suffer from leakage. For example, in some memory such as, but not limited to, static random access memory (SRAM), there may be some leakage in the periphery of SRAM memory. For example, in a standby state, the memory may not be in operation and/or relatively minimal operation, where the memory may be ready for next access, but not accessed for a time period. External management of the memory may be performed by such external management approaches, such as, but not limited to, an external controller and/or some other form of external environment from the memory.

The approaches utilizing external management to help facilitate alleviation of leakage may include external management of the memory mode at each moment, which may add complexity. For example, the utilization of external management to get in and out of a retention state (i.e., shutting down the periphery completely), may cause complexity in the process, where signals may be communicated back and forth to facilitate approval of some form of communication handshake that power back/power up again has finished. Additionally, getting out of the retention state may cause a significant number of clock cycles, which may a significant cost to the system.

All subject matter discussed in this section of this document is not necessarily prior art and may not be presumed to be prior art simply because it is presented in this section. Plus, any reference to any prior art in this description is not and should not be taken as an acknowledgement or any form of suggestion that such prior art forms parts of the common general knowledge in any art in any country. Along these lines, any recognition of problems in the prior art are discussed in this section or associated with such subject matter should not be treated as prior art, unless expressly stated to be prior art. Rather, the discussion of any subject matter in this section should be treated as part of the approach taken towards the particular problem by the inventor(s). This approach in and of itself may also be inventive. Accordingly, the foregoing summary is illustrative only and not intended to be in any way limiting. In addition to the illustrative aspects, embodiments, and features described above, further aspects, embodiments, and features will become apparent by reference to the drawings and the following detailed description.

### SUMMARY

Described herein are various illustrative devices, systems, and methods for selective source bias for a periphery of a memory. Some example systems may include one or more inverter circuits. The example systems may include biasing one or more transistors include in the one or more inverter circuits. The systems, and methods may include knowing a logic state of substantially most of the nets in the inverter circuits.

As a result, minimizing leakage may be facilitated, in accordance with various embodiments, which in turn may lead to savings.

The foregoing summary is illustrative only and not intended to be in any way limiting. In addition to the illustrative aspects, embodiments, and features described above, further aspects, embodiments, and features will become apparent by reference to the drawings and the following detailed description.

### BRIEF DESCRIPTION OF DRAWINGS

Subject matter is particularly pointed out and distinctly claimed in the concluding portion of the specification. The foregoing and other features of the present disclosure will become more fully apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings.

FIG. 1 illustrates an overview of a bitcell array source bias.

FIGS. 2A and 2B illustrate some principle of SSB and its applicability to memory periphery as described herein, in accordance with various embodiments.

FIG. 3 illustrates a schematic of a circuit diagram, in accordance with one or more embodiments.

FIG. 4 illustrates types of supply and/or ground switch circuits, which may be utilized, in accordance with various embodiments.

FIG. 5 illustrates types of supply and/or ground switch circuits.

FIG. 6 illustrates an example computer device.

FIGS. 7A and 7B illustrate a top level of LDP and LCTL, including an example of SSB implementation in LCTL-segment control, in accordance with various embodiments.

FIGS. 8A and 8B illustrate a top level of LDP and LCTL, including an example of SSB implementation in LDP cell, in accordance with various embodiments.

FIGS. 9A, 9B, and 9C illustrate SSB implementation in LDP cell-Bitlines circuits, in accordance with various embodiments.

FIGS. 10A and 10B illustrate SSB implementation in LDP cell-Sense Amp, in accordance with various embodiments.

FIGS. 11A and 11B illustrate exception handling (3)—type B switches activated according to logic state, in accordance with various embodiments.

FIG. 12 illustrates some waveform signals received during the utilization of SSB implementation, in accordance with various embodiments.

FIG. 13 illustrates at least some examples of logic conditions for entering Selective SB, in accordance with various embodiments.

FIG. 14 illustrates some examples of benchmark results.

### DETAILED DESCRIPTION

The following description sets forth various examples along with specific details to provide a thorough understanding of claimed subject matter. It will be understood by those skilled in the art after review and understanding of the present disclosure, however, that claimed subject matter may be practiced without some or more of the specific details disclosed herein. Further, in some circumstances, well-known methods, procedures, systems, components and/or circuits have not been described in detail in order to avoid unnecessarily obscuring claimed subject matter.

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the aspects of the present disclosure, as generally described herein, and illustrated in the Figures, can be arranged, substituted, combined, and designed in a wide variety of different configurations, all of which are explicitly contemplated and make part of this disclosure.

This disclosure is drawn, inter alia, to methods, apparatus, and circuit systems to facilitate a selective source bias (SSB) design/approach (hereafter, SSB) to facilitate a reduction of leakage in periphery of SRAM during various states such as, but not limited to, a standby state. In some embodiments, the SSB may be activated automatically by chip select input (CS_N), which may include normal set up and hold. The CS_N may facilitate no need to activate and wait for more than one cycle or subsequently sample an input and/or an out of memory indicating that the power is nominal. In systems where multiple SRAM chips are present, or where SRAM may be integrated with other devices on a bus, Chip Select (CS) line may determine when a particular SRAM chip is active and may interact with the rest of the system and/or some alternative methods. In some embodiments, the SSB may be activated along with an array source bias to facilitate a reduction in leakage. In some embodiments, selected transistors may be biased. In some embodiments, supply and ground level may be biased but not signals. In some embodiments, a gate of one or more biased transistors may be maintained “fully off”, which may further improve reduction in leakage.

It should be appreciated that the standby may include a state memory inactive and/or substantially inactive (i.e., may be ready for a subsequent access but may not be accessed for a period of time).

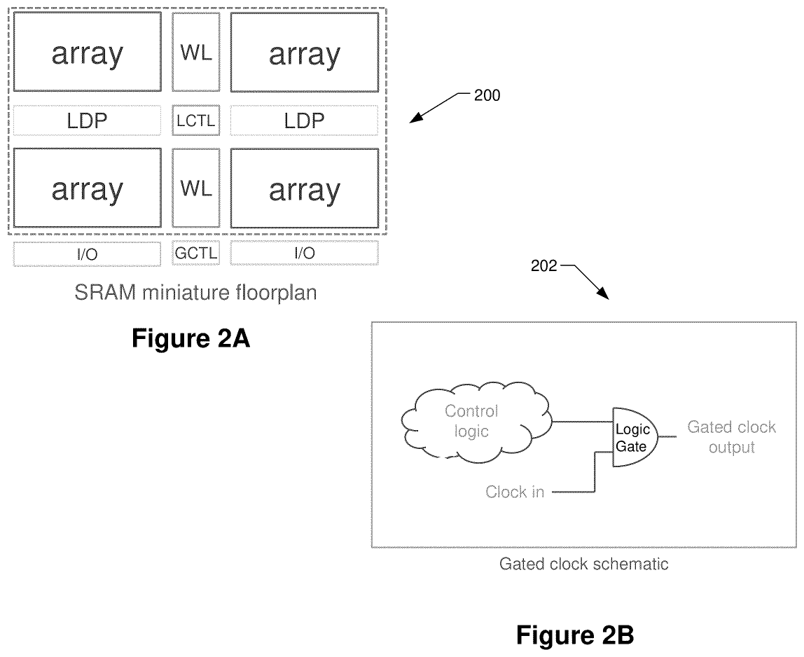

Prior to turning to the Figures, a brief introduction to some of the components included in the Figures may be provided. For example, FIGS. 2B, 6B, 7B, 8C, 9B, and 10B may include a floorplan description of memory, which may be utilized to help facilitate implementation of at least some of the various embodiments disclosed herein. These Figures, including the floorplans, may include a variety of components that may be in associated/included in SRAM such as, but not limited to, a sense-amplifier and/or Word Line drivers Some examples of components/units may include, but not limited to the following:
GCTL—global control unit, which may include clock control, address latches, and/or control for data input/output cells.
i/o—these may be data in and out drivers.
LDP—Local Data Path, which may be a component that may include a sense-amplifier, write driver, and/or read and write multiplexers (may be also known as muxes).
WL—Word Line drivers, which may include some address decode logic.
LCTL—Local Control unit that may be configured to manage a Word Line selection and control for the components/units in LDP.
Array—may be bitcell array.

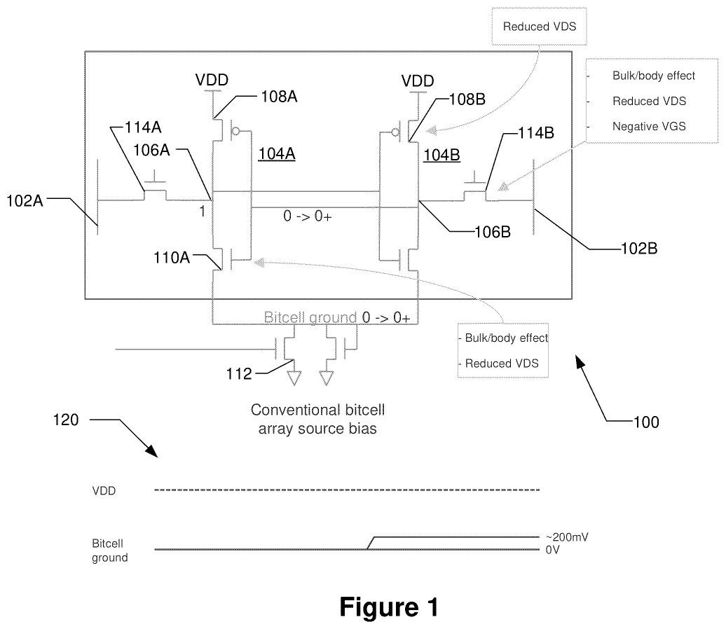

Turning now to FIG. 1, FIG. 1 illustrates an overview of a bitcell array source bias. In FIG. 1, an SRAM bitcell (hereafter, bitcell) 100 may include a pair of complementary bitlines a first bitline 102A and a second bitline102B. The bitcell 100 may include a first inverter 104A, a second inverter 104B, a first data node 106A, and a second data node 106B. In FIG. 1, the first inverter 104A may include a first PMOS transistor 108A, which may have its source and drain terminals coupled between VDD and the first data node 106A with its gate coupled to the second data node 106B. The data nodes 106A and 106B may operate as two complementary storage nodes in the bitcell 100. The first inverter 104A may include a first NMOS transistor 110A, which may have its drain coupled with the first data node 106A and its source coupled with a bitcell ground 112. As shown in FIG. 1, the gate of the first NMOS transistor 110A may be coupled with the second data node 106B. The second inverter 104B may include a second PMOS transistor 108B, which may have its source and drain terminals coupled between VDD and the second data node 106B with its gate coupled with the first data node 106A. Additionally, the second inverter 104B may include a second NMOS transistor 110B, where its drain may be couple with the second data node 106B and its source coupled with the bitcell ground 112. As shown, the second NMOS transistor 110B may have its gate coupled with the first data node 106A. Additionally, the bitcell 100 may include a first NMOS access device 114A, which may be disposed between the first bitline 102A and the first data node 106A, and a second NMOS access device 114B, which may be disposed between the second bitline 102B and the second data node 106B.

It should be appreciated that FIG. 1 may be shown to facilitate ease of understanding the claimed subject matter. The bitcell 100 may help to provide some context with respect to how the claimed subject matter may be utilized to reduce the leakage, in accordance with one or more embodiments. In FIG. 1, the supply and ground levels may be biased, in accordance with one or more embodiments. Additionally, as will be described later, in FIG. 1, all of the transistor may be in a state of “fully off”, where the gates of the biased transistors may be in remain “fully off”, in accordance with one or more embodiments.

In FIG. 1, the 6 transistor bitcell 100 may include the bitcell ground 112, which may be coupled in a conventional manner with the bitcell 100 to facilitate a source bias. As shown, the bitcell ground 112 may comprise of two device, where one of the transistors of the ground 112 may be configured as a switch while the other may be configured as a diode.

As shown in FIG. 1, the bitcell 100 may include a state of the internal nets to be 1 at the first data node 106A, which may correspond to 0 at the other side. Accordingly, three of the transistors may be in an off state (i.e., the first NMOS transistor 110A, the second PMOS transistor 108A, and the second NMOS access device 114B). Focusing on the second PMOS transistor 108B, the second PMOS transistor 108B (i.e., pull-up PMOS) may be receiving from the source bias may be a reduced VDS. As shown in the graph 120, the reason that the second PMOS transistor 108B may experience the reduced VDS may be due to the bias may bring up the bitcell ground by approximately 200 mV, which may be lower or higher depending on VDD, transistor type, and so forth. Accordingly, the second PMOS transistor 108B may only receiving reduced VDS. As a result, a reduction in leakage may be facilitated, in accordance with one or more embodiments.

On the other side of the bitcell 100, the first NMOS transistor 110A (i.e., pull-down NMOS) may experience reduced VDS. However, in addition to the reduced VDS, the first NMOS transistor 110A may experience a bulk/body effect. The bulk/body effect may result when the source voltage and the body (i.e., bulk) different (e.g., source voltage being higher than the body), which may increase the VD. Here again, a reduction in leakage may be facilitated, in accordance with one or more embodiments.

In the bitcell 100 of FIG. 1, the second NMOS access device 114B (i.e., pass gate) may be in the off state, which may be substantially the similar state as the first access device 114A. As shown in FIG. 1, the second NMOS access device 114B may experience bulk/body effect, reduced VDS, and a negative VGS. The negative VGS may be the result of a word line coupled with the second NMOS access device 114B being pulled 0, while a source may be slightly higher (e.g., approximately 200 mV). Accordingly, of the three transistors that are off, the first NMOS transistor 110A, the second PMOS transistor 108A, and the second NMOS access device 114B, one may experience all three effects.

As mentioned, the bitcell shown and described in FIG. 1 may facilitate a further understanding of the present disclosure by providing context and comparison. In the periphery of an SRAM, a majority and/or substantially all of the transistors may experience all of the previously described effects, in accordance with one or more embodiments. As a result, leakage in an SRAM periphery may be reduced.

Briefly, an SSB design as disclosed herein, which may be implemented in a periphery of a memory, may facilitate a fast approach to significantly reduce standby current because there may be no power up or power down processes involved, in accordance with one or more embodiments. In one example, substantially no extra cycles may be needed and may include a dedicated input and/or chip select as previously mentioned to get in or out of the mode. In another example, the relevant control input may have a reasonable setup time. In yet another example, substantially no inrush glitch may occur (i.e., a phenomenon experienced when powering up the periphery and/or the entire SRAM). In another example, the energy cost for entering or exiting SSB may be below the energy cost of an access. In another example, logic signals may maintain their voltages (i.e., bias levels are not propagated to logic signals). Additionally, current in “off” transistors (PMOS and NMOS) may be reduced including Bulk/Body effect to increase |V_{T}|, Reduced |V_{DS}|, and/or Negative V_{GS} for NMOS, positive V_{GS} for PMOS, as previously described.

FIGS. 2A and 2B illustrate some principle of SSB and its applicability to memory periphery as described herein, in accordance with various embodiments. For example, Static Random Access Memory (SRAM) periphery features and its suitability for SSB implementation.

FIG. 2A illustrates a simplified view of an SRAM miniature floor plan (afterwards, floorplan 200), which may be a top level of memory. The floorplan 200 may include a pair of local data paths (LDP), a pair of word line drivers (WL), a local control (LCTL), a global control (GCTL), a pair of input/output (I/O), and a plurality of bitcell arrays (array).

FIG. 2B illustrates a simplified view of a gated clock schematic. In FIG. 2B, a gated clock schematic 202 may include a control logic communicatively coupled to a logic gate, a direct signal (e.g., clock in) communicatively coupled to the logic gate, and a gated clock output from the logic gate. References to the logic states of the gated clocks may be shown by FIG. 2B.

In FIG. 2A, the LDP may include various components such as, but not limited to, sense amplifiers, write drivers, multiplexers (mux), and so forth. The inputs of the LDP may be sense enabled and write enabled, where a significant number of nets, including bitlines, may pre-charged facilitating a known state. Some of the other components may be controlled by gated clocks (e.g., see FIG. 2B) such as sense enable and write enable. Accordingly, logic in the LDP may be controlled by gated clock inputs such as sense enable and/or write enable, which may assist inputs, where the inactive gated clock may help to confirm a state of the nets in following logic (i.e., driven by the gated clock input).

The LCTL may include control for word line drivers and may be configured to be the origin of the sense enable and write enable. The LCTL may include decode logic, which may be changed to have substantially all its outputs in a known state when SSB mode may be active. Additionally, the LCTL may include gated clock circuits, where in the standby mode (i.e., SSB mode), the gated clocks may be inactive resulting in a known logic state.

Referring now to GCTL, the GCTL may include address and a variety of input latches, where the address and input latches (i.e., nets) may be forced to a known state by reasonable resource expenditure. For example, the nets may be forced to a known logic state when a signal is received, by allowing the normal logic state, responsive to the received signal, to propagate. The received signal may be a signal such as, but not limited to, a dedicated input (e.g., CLK) or a chip select (e.g., CS_N), and accordance with various embodiments. However, since the forcing situation may not occur frequently, the forcing of the logic states of the nets may be but one approach based, at least in part, on the design requirements. Additionally, the GCTL may include partial address decoding, where once the logic state of the address latches is known, the logic state of the decode logic may also be known. As previously described, the GCTL may include clock generation circuits, where their logic states may be known when the main inputs (e.g., dedicated input/CLK and chip select/CS_N) are in the off state. It may be appreciated that knowledge of the logic state of the nets helps to facilitate the claimed subject matter.

The WL, being gated clocks, may behave like gated clocks (i.e., when the input is known, the logic states of the nets are known. For example, when the SSB mode is active, the WL may be inactive.

In the I/O, there may be an exception to be managed because due to its properties, the input data and/or the output data may not be known. The logic states of the I/O may not be forced because changing of the input and/or output would not be desired. For example, it would not be desirable to change a value recently read from the memory. Management of the exception will be described subsequently.

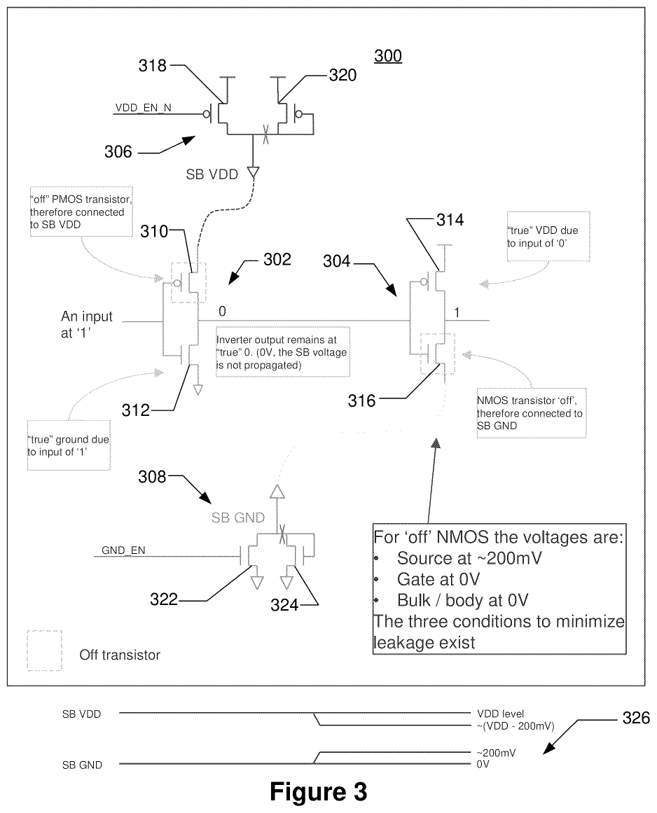

FIG. 3 illustrates a schematic of a circuit diagram, in accordance with one or more embodiments. In FIG. 3, a circuit 300 may include a first inverter circuit 302 communicatively coupled with a second inverter circuit 304. As shown, the first inverter circuit 302 may be communicatively coupled with a source bias (SB) VDD 306, while the second inverter circuit 302 may be communicatively coupled with an SB ground (SB GND) 308.

In FIG. 3, the first inverter circuit 302 may include a first PMOS transistor 310 and a first NMOS transistor 312. The second inverter circuit 304 may include a second PMOS transistor 314 and a second NMOS transistor 316. The SB VDD 306 may include two PMOS transistors, a first PMOS transistor configured as a voltage source switch 318 and a second PMOS transistor configured as a voltage source diode 320. Additionally, the SB GND 308 may include two NMOS transistors, a first NMOS transistor configured as a ground switch 322 and a second NMOS transistor configured as a ground diode 324. As will be described, the voltage source diode 320 and the ground diode 324 may or may not be necessary as shown by “X”, in accordance with various embodiments. The source of the first PMOS transistor 310 may be communicatively coupled to the SB VDD 306, and the drain of the second NMOS transistor 316 may be communicatively coupled with the SB GND 308 as shown.

As shown in FIG. 3, the logic states of substantially all of the nets may be determined. In the one example shown, in a standby mode (SSB mode), an input to the first inverter circuit 302 may be a logic state of 1, which may result in a logic state of 0 to the input of the second inverter 304. The first PMOS transistor 310 may be off condition may be communicatively coupled and deactivate the switch and may receive substantially all of the effects that may be available from bias. The logic state may be 1, which may be higher than the supply, which may resemble negative VGS.

In FIG. 3, the BS GND 308 may be biased up (e.g., approximately, 200 mV), and the output of the first inverter circuit 302 may be a true 0 (i.e., the SB voltage may not be propagated). The second NMOS transistor 316 may be may be in the off condition, and may be communicatively coupled to SB GND 308. Accordingly, the biased supply and ground may be communicatively coupled to transistors which may be in the off condition (e.g., first PMOS transistor 310 and the second NMOS transistor 316), which may have the following result: biased levels may not be propagated to the logic signals, a signal at a logic state of 0 may remain at 0V and may not be raised to ~200 mV, a signal at a logic state of 1 may remain at VDD level and may not drop to (VDD−200 mV), and may facilitate a quick recovery without significant energy cost because the non-biased transistors may remain at normal voltage and are not biased. As a result, current in the transistors in the off condition (e.g., first PMOS transistor 310 and the second NMOS transistor 316) may be reduced in a least three manners, bulk/body effect to facilitate an increase in |V_{T}|, reduced |V_{DS}|, and negative V_{GS} for NMOS transistor(s), positive V_{GS} for PMOS transistor(s) (e.g., first PMOS transistor 310 and the second NMOS transistor 316). Accordingly, the three manners (i.e., conditions), which may occur in each of the biased transistors, may help to facilitate minimizing leakage, in accordance with various embodiments, which in turn may lead to savings.

In order to facilitate an exit from the SB mode, one may need to bring back voltage. However, bringing back the voltage may not be a full uprise of the supply or a pull down or full swing of the ground, but instead, it may involve bring the circuit back from the biased level back to 0 or to the full VDD level, where the process may not be very slow. Accordingly, one solution approach may involve utilizing a setup time prior to the clock with no need for a handshake that may be utilized to indicate that power up is completed and the like.

Prior to turning to the next Figure, in FIG. 3, graph 326 may illustrate the biased levels as shown.

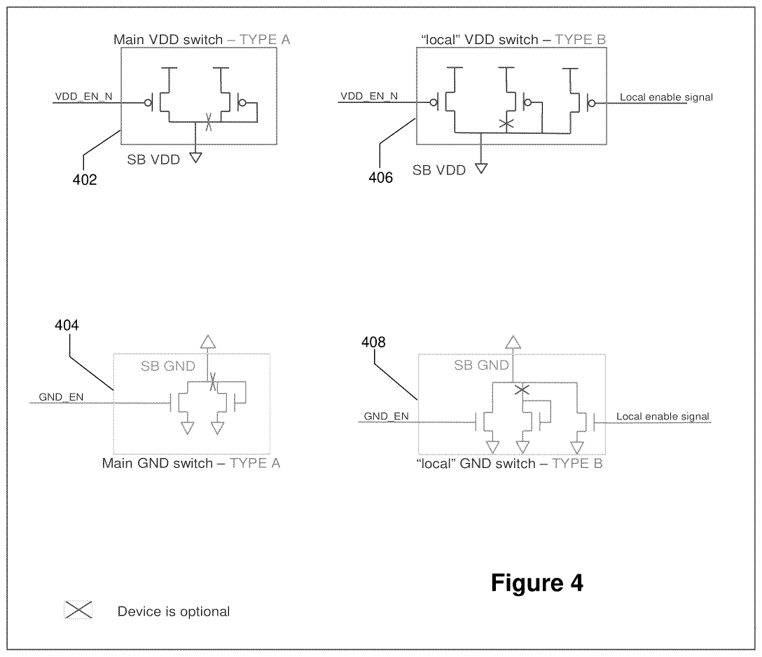

FIG. 4 illustrates types of supply and/or ground switch circuits, which may be utilized, in accordance with various embodiments. As shown in FIG. 4, some types of switches may include a main VDD switch (Type A) 402 and a main GND switch (Type A) 404. The main VDD switch 402 and the main GND switch 404 may each have a global control, as previously described.

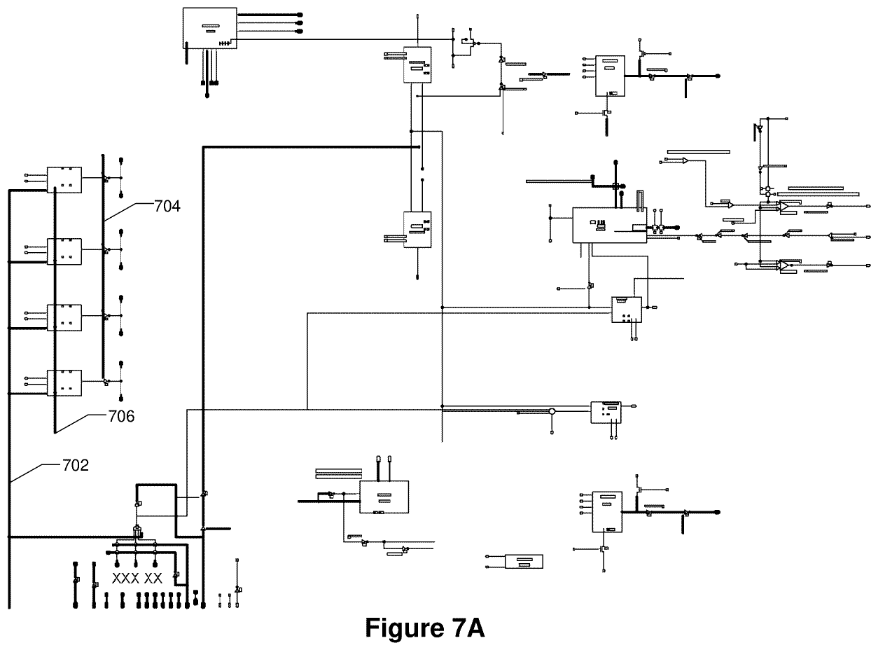

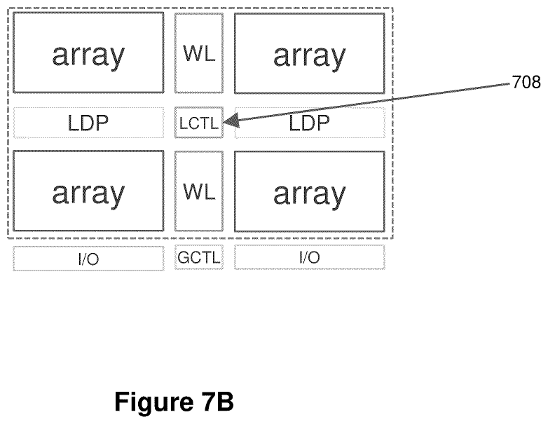

Some alternative types may include a local VDD switch (Type B) 406 and a local GND switch (Type B) 408, which may be utilized to address exceptions, where an exception may include a piece of logic, whose logic state may not be known when SSB mode is active. In some examples, one signal may facilitate determination of the logic state of substantially all of the other signals in the piece of logic shown. In such case it may possible to utilize a local signal for control, which may include a determination of which of the switches may be active and which of the switches may not be active. It should be appreciated that a local enable signal may substantially be the same for both local switches 406 and 408, and accordingly, only one may be disconnected. Further details may be described and shown subsequently (e.g., FIGS. 7A and 7B).

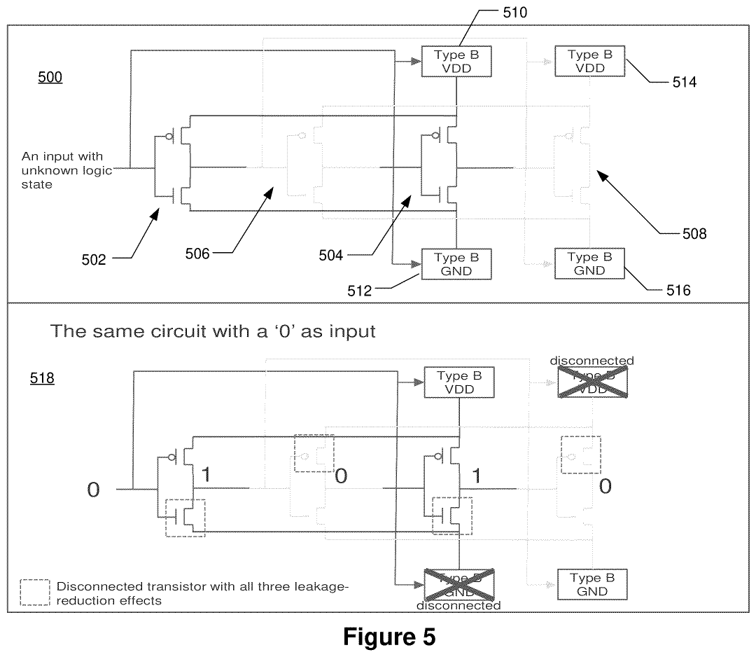

FIG. 5 illustrates types of supply and/or ground switch circuits. As shown in FIG. 5, utilization of Type B switches (406 and 408 shown in FIG. 4) may be shown. In FIG. 5, a circuit 500 may include a first inverter 502, a second inverter 504, a third inverter 506, and a fourth inverter 508 communicatively coupled as shown. Additionally, the first and second inverters 502 and 504 may be communicatively coupled with a first Type B VDD 510 and a first Type B GND 512. The third inverter and the fourth inverter 506 and 508 may be communicatively coupled with a third Type B VDD 514 and a fourth Type B GND 516.

In FIG. 5, in cases of unknown logic state of an input, it may be a possibility that one net state may cause to determine the logic state of one or more of the others in a one-to-one manner. Accordingly, the local VDD switch (Type B) and local GND switch (Type B) may be utilized for leakage reduction in such cases. For example, in some embodiments, four inverters in a row 502, 504, 506, and 508 may be communicatively coupled as shown. During normal operation, substantially all supplies may be communicatively coupled by the global control signals, EN_VDD_N and EN_VDD (not shown). However, in the SSB mode, the global control signals may disconnect the Type B switches as shown in a duplicate circuit 518 having an input logic state of 0. The parallel switch may be controlled by a local control input, which commonly may open one of the VDD or GND and shut the other.

In some embodiments, the claimed subject matter may be described utilizing a simulation model. For example, a memory model may be utilized for development and to determine benchmark results. This simulation model may be performed in a similar manner as for developing a general purpose SPRAM in the related technology.

As a result, minimizing leakage may be facilitated, in accordance with various embodiments, which in turn may lead to savings.

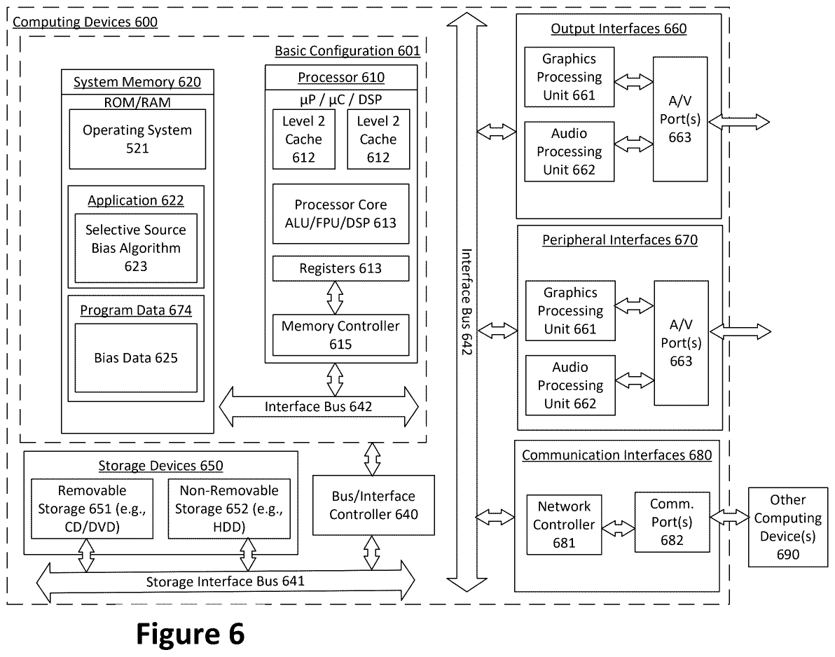

FIG. 6 illustrates an example computer device. FIG. 6 is a block diagram illustrating an example computing device 600, such as might be embodied by a person skilled in the art, which is arranged in accordance with at least some embodiments of the present disclosure. In one example configuration, computing device 600 may include one or more processors 610 and system memory 620. A memory bus 630 may be used for communicating between the processor 610 and the system memory 620.

Depending on the desired configuration, processor 610 may be of any type including but not limited to a microprocessor (μP), a microcontroller (μC), a digital signal processor (DSP), or any combination thereof. Processor 610 may include one or more levels of caching, such as a level one cache 611 and a level two cache 612, a processor core 613, and registers 614. The processor core 613 may include an arithmetic logic unit (ALU), a floating-point unit (FPU), a digital signal processing core (DSP Core), or any combination thereof. A memory controller 615 may also be used with the processor 610, or in some implementations the memory controller 615 may be an internal part of the processor 610.

Depending on the desired configuration, the system memory 620 may be of any type including but not limited to volatile memory (such as RAM), non-volatile memory (such as ROM, flash memory, etc.) or any combination thereof. System memory 620 may include an operating system 621, one or more applications 622, and program data 624. Application 622 may include selective source bias management algorithm 623 that is arranged to perform the functions as described herein including the functional blocks and/or actions described. Program Data 624 may include, among other information described, wake up bias data 625 for use with the process selective source bias management algorithm 623. In some example embodiments, application 622 may be arranged to operate with program data 624 on an operating system 621 such that implementations of the management of a wake-up circuit as part of an integrated circuit may be provided as described herein. For example, apparatus described in the present disclosure may comprise all or a portion of computing device 600 and be capable of performing all or a portion of application 622 such that facilitating management of a process corner in an integrated circuit as described herein. This described basic configuration is illustrated in FIG. 6 by those components within dashed line 601.

Computing device 600 may have additional features or functionality, and additional interfaces to facilitate communications between the basic configuration 601 and any required devices and interfaces. For example, a bus/interface controller 640 may be used to facilitate communications between the basic configuration 601 and one or more data storage devices 650 via a storage interface bus 641. The data storage devices 650 may be removable storage devices 651, non-removable storage devices 652, or a combination thereof. Examples of removable storage and non-removable storage devices include magnetic disk devices such as flexible disk drives and hard-disk drives (HDD), optical disk drives such as compact disk (CD) drives or digital versatile disk (DVD) drives, solid state drives (SSD), and tape drives to name a few. Example computer storage media may include volatile and nonvolatile, removable and non-removable media implemented in any method or technology for storage of information, such as computer readable instructions, data structures, program modules, or other data.

System memory 620, removable storage 651 and non-removable storage 652 are all examples of computer storage media. Computer storage media includes, but is not limited to, RAM, ROM, EEPROM, flash memory or other memory technology, CD-ROM, digital versatile disks (DVD) or other optical storage, magnetic cassettes, magnetic tape, magnetic disk storage or other magnetic storage devices, or any other medium which may be used to store the desired information, and which may be accessed by computing device 600. Any such computer storage media may be part of device 600.

Computing device 600 may also include an interface bus 642 for facilitating communication from various interface devices (e.g., output interfaces, peripheral interfaces, and communication interfaces) to the basic configuration 701 via the bus/interface controller 640. Example output interfaces 660 may include a graphics processing unit 661 and an audio processing unit 662, which may be configured to communicate to various external devices such as a display or speakers via one or more A/V ports 663. Example peripheral interfaces 660 may include a serial interface controller 671 or a parallel interface controller 672, which may be configured to communicate with external devices such as input devices (e.g., keyboard, mouse, pen, voice input device, touch input device, etc.) or other peripheral devices (e.g., printer, scanner, etc.) via one or more I/O ports 673. An example communication interface 680 includes a network controller 681, which may be arranged to facilitate communications with one or more other computing devices 690 over a network communication via one or more communication ports 682. A communication connection is one example of a communication media. Communication media may typically be embodied by computer readable instructions, data structures, program modules, or other data in a modulated data signal, such as a carrier wave or other transport mechanism, and may include any information delivery media. A “modulated data signal” may be a signal that has one or more of its characteristics set or changed in such a manner as to encode information in the signal. By way of example, and not limitation, communication media may include wired media such as a wired network or direct-wired connection, and wireless media such as acoustic, radio frequency (RF), infrared (IR) and other wireless media. The term computer readable media as used herein may include both storage media and communication media.

Computing device 600 may be implemented as a portion of a small-form factor portable (or mobile) electronic device such as a cell phone, a personal data assistant (PDA), a personal media player device, a wireless web-watch device, a personal headset device, an application specific device, or a hybrid device that includes any of the above functions. Computing device 600 may also be implemented as a personal computer including both laptop computer and non-laptop computer configurations. In addition, computing device 600 may be implemented as part of a wireless base station or other wireless system or device.

It should be appreciated after review of this disclosure that it is contemplated within the scope and spirit of the present disclosure that the claimed subject matter may include a wide variety of integrated circuit devices. Accordingly, the claimed subject matter is not limited in these respects.

Some portions of the foregoing detailed description are presented in terms of algorithms or symbolic representations of operations on data bits or binary digital signals stored within a computing system memory, such as a computer memory. These algorithmic descriptions or representations are examples of techniques used by those of ordinary skill in the data processing arts to convey the substance of their work to others skilled in the art. An algorithm is here, and generally, considered to be a self-consistent sequence of operations or similar processing leading to a desired result. In this context, operations or processing involve physical manipulation of physical quantities. Typically, although not necessarily, such quantities may take the form of electrical or magnetic signals capable of being stored, transferred, combined, compared or otherwise manipulated. It has proven convenient at times, principally for reasons of common usage, to refer to such signals as bits, data, values, elements, symbols, characters, terms, numbers, numerals or the like. It should be understood, however, that all of these and similar terms are to be associated with appropriate physical quantities and are merely convenient labels. Unless specifically stated otherwise, as apparent from the following discussion, it is appreciated that throughout this specification discussion utilizing terms such as “processing,” “computing,” “calculating,” “determining” or the like refer to actions or processes of a computing device that manipulates or transforms data represented as physical electronic or magnetic quantities within memories, registers, or other information storage devices, transmission devices, or display devices of the computing device.

Claimed subject matter is not limited in scope to the particular implementations described herein. For example, some implementations may be in hardware, such as those employed to operate on a device or combination of devices, for example, whereas other implementations may be in software and/or firmware. Likewise, although claimed subject matter is not limited in scope in this respect, some implementations may include one or more articles, such as a signal bearing medium, a storage medium and/or storage media. This storage media, such as CD-ROMs, computer disks, flash memory, or the like, for example, may have instructions stored thereon that, when executed by a computing device such as a computing system, computing platform, or other system, for example, may result in execution of a processor in accordance with claimed subject matter, such as one of the implementations previously described, for example. As one possibility, a computing device may include one or more processing units or processors, one or more input/output devices, such as a display, a keyboard and/or a mouse, and one or more memories, such as static random-access memory, dynamic random-access memory, flash memory, and/or a hard drive.

There is little distinction left between hardware and software implementations of aspects of systems; the use of hardware or software is generally (but not always, in that in certain contexts the choice between hardware and software can become significant) a design choice representing cost vs. efficiency tradeoffs. There are various vehicles by which processes and/or systems and/or other technologies described herein can be affected (e.g., hardware, software, and/or firmware), and that the preferred vehicle will vary with the context in which the processes and/or systems and/or other technologies are deployed. For example, if an implementer determines that speed and accuracy are paramount, the implementer may opt for a mainly hardware and/or firmware vehicle; if flexibility is paramount, the implementer may opt for a mainly software implementation; or, yet again alternatively, the implementer may opt for some combination of hardware, software, and/or firmware.

The foregoing detailed description has set forth various embodiments of the devices and/or processes via the use of block diagrams, flowcharts, and/or examples. Insofar as such block diagrams, flowcharts, and/or examples contain one or more functions and/or operations, it will be understood by those within the art that each function and/or operation within such block diagrams, flowcharts, or examples can be implemented, individually and/or collectively, by a wide range of hardware, software, firmware, or virtually any combination thereof. In one embodiment, several portions of the subject matter described herein may be implemented via Application Specific Integrated Circuits (ASICs), Field Programmable Gate Arrays (FPGAs), digital signal processors (DSPs), or other integrated formats. However, those skilled in the art will recognize that some aspects of the embodiments disclosed herein, in whole or in part, can be equivalently implemented in integrated circuits, as one or more computer programs running on one or more computers (e.g., as one or more programs running on one or more computer systems), as one or more programs running on one or more processors (e.g., as one or more programs running on one or more microprocessors), as firmware, or as virtually any combination thereof, and that designing the circuitry and/or writing the code for the software and/or firmware would be well within the skill of one of skilled in the art in light of this disclosure. In addition, those skilled in the art will appreciate that the mechanisms of the subject matter described herein are capable of being distributed as a product in a variety of forms, and that an illustrative embodiment of the subject matter described herein applies regardless of the particular type of signal bearing medium used to actually carry out the distribution. Examples of a signal bearing medium include, but are not limited to, the following: a recordable type medium such as a flexible disk, a hard disk drive (HDD), a Compact Disc (CD), a Digital Versatile Disk (DVD), a digital tape, a computer memory, etc. ; and a transmission type medium such as a digital and/or an analog communication medium (e.g., a fiber optic cable, a waveguide, a wired communications link, a wireless communication link, etc.).

Those skilled in the art will recognize that it is common within the art to describe devices and/or processes in the fashion set forth herein, and thereafter use engineering practices to integrate such described devices and/or processes into data processing systems. That is, at least a portion of the devices and/or processes described herein can be integrated into a semiconductor integrated circuit system via a reasonable amount of experimentation. Those having skill in the art will recognize that a typical semiconductor integrated circuit system generally may be included in one or more of a system unit housing, a video display device, a memory such as volatile and non-volatile memory, processors such as microprocessors and digital signal processors, computational entities such as operating systems, drivers, graphical user interfaces, and applications programs, one or more interaction devices, such as a touch pad or screen, and/or control systems including feedback loops and control motors (e.g., feedback for sensing position and/or velocity; control motors for moving and/or adjusting components and/or quantities). A typical semiconductor integrated circuit system may be implemented utilizing any suitable commercially available components, such as those typically found in computing/communication and/or network computing/communication systems.

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

Reference in the specification to “an implementation,” “one implementation,” “some implementations,” or “other implementations” may mean that a particular feature, structure, or characteristic described in connection with one or more implementations may be included in at least some implementations, but not necessarily in all implementations. The various appearances of “an implementation,” “one implementation,” or “some implementations” in the preceding description are not necessarily all referring to the same implementations.

While certain exemplary techniques have been described and shown herein using various methods and systems, it should be understood by those skilled in the art that various other modifications may be made, and equivalents may be substituted, without departing from claimed subject matter. Additionally, many modifications may be made to adapt a particular situation to the teachings of claimed subject matter without departing from the central concept described herein. Therefore, it is intended that claimed subject matter is not limited to the particular examples disclosed, but that such claimed subject matter also may include all implementations falling within the scope of the appended claims, and equivalents thereof.

Utilizing the simulation model, once the model was fully functional, substantially all SSB related circuits may be implemented/integrated as follows:
Technology may be GF 22n FDX
Relatively few optimizations for low speed/low dynamic power
No layout, where the simulations may be performed utilizing the methodology including capacitance & resistance estimations
Mux-4, 2SEG was tested, usually at max configuration—2kx128, but also 2kx32 was tested for some results.

FIGS. 7A and 7B illustrate SSB implementation in LCTL 708 shown in FIG. 7B segment control, in accordance with various embodiments. Shown in FIGS. 6A and 6B may be the following:
Top level view
For the switched supplies:
The AREADY 702 signal may be an indication of SSB mode
The global supply VDD_CNTR 704 shown in FIG. 7A
The global ground GND_CNTR 706 shown in FIG. 7A
These supplies may be coupled to the vast majority of the cells in the schematic shown
This is possible because of at least some of the following reasons:
   Gated clocks may be disabled
   Address decoders may be set to known state when AREADY=0
As a result, the logic state of substantially all the signals in LCTL may be fixed (i.e., the basic condition for SSB).

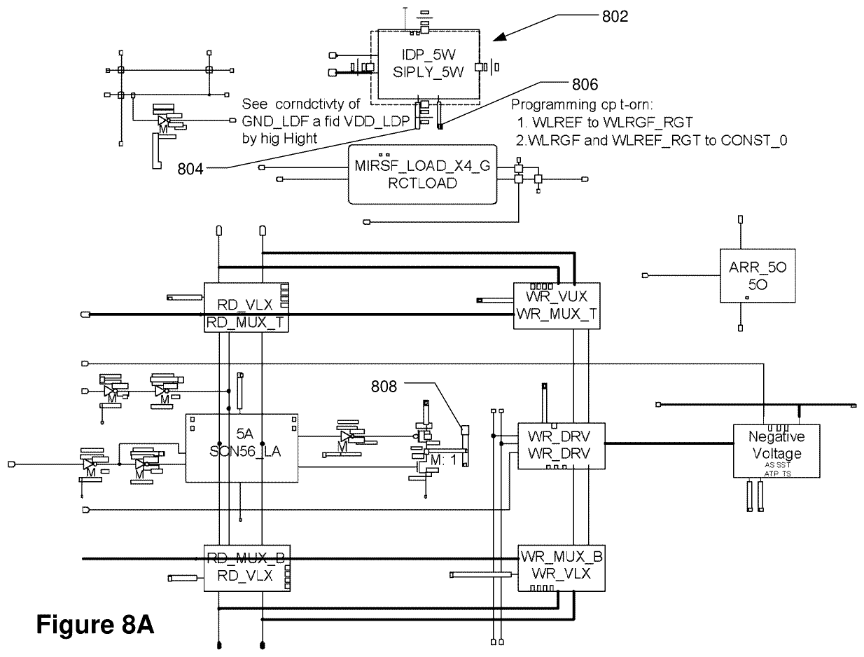

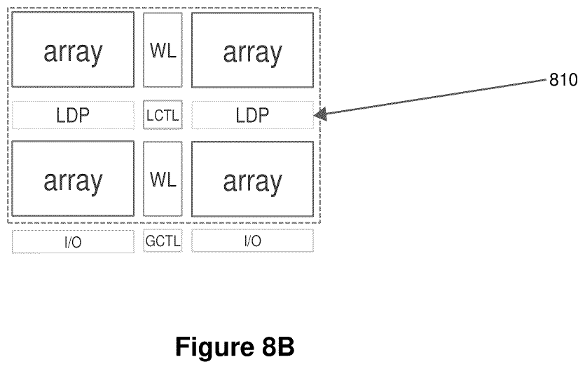

FIGS. 8A and 8B illustrate SSB implementation in LDP cell 810 shown in FIG. 8B, in accordance with various embodiments. Shown in FIGS. 8A and 8B may be the following:
The switch cell 802 may have GND_LDP 804 and VDD_LDP 806 as outputs shown in FIG. 8A
For the purpose of having substantially all inputs at known logic state, substantially all pins of the mux control bus YSEL_N[3:0] may be driven to “1”
Inverters at the cell's top level may be coupled as shown in the some of the previous figures (e.g., FIG. 5)
RDATA 808 may be the read data bus line, where its tri-state driver may have both NMOS and PMOS coupled to the switch-able supplies
   RDATA 808 may maintain its logic state but the level may be shifted to 200 mV or (VDD−200 mV)
   In GDP cell, it may be seen how RDATA exception may be managed.

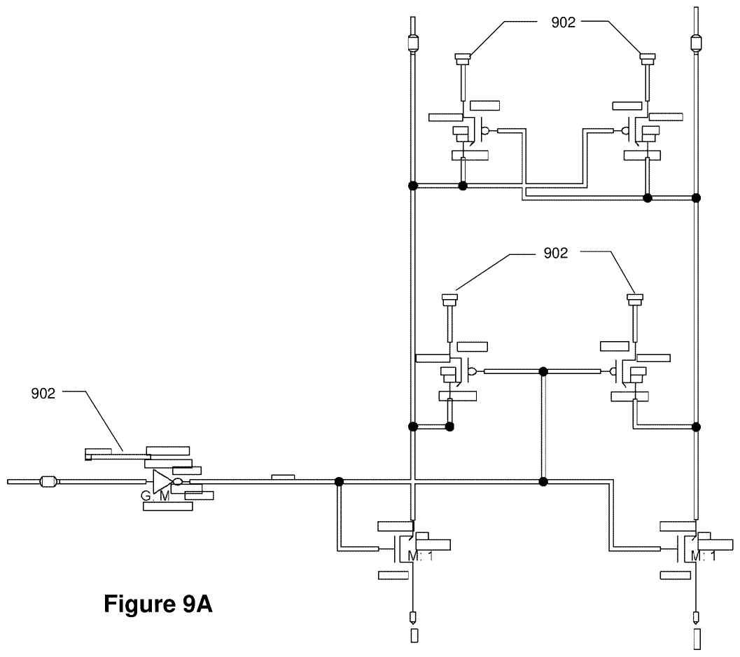

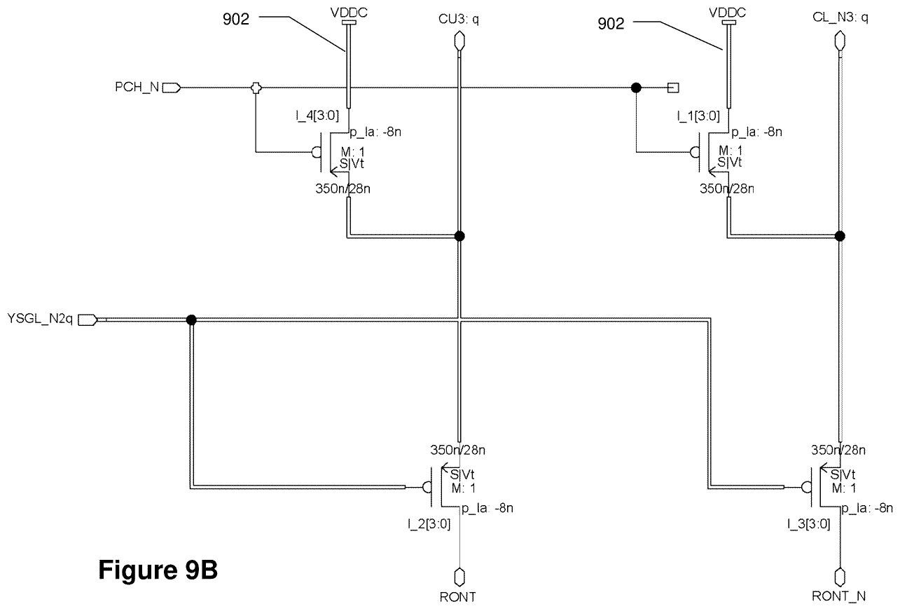

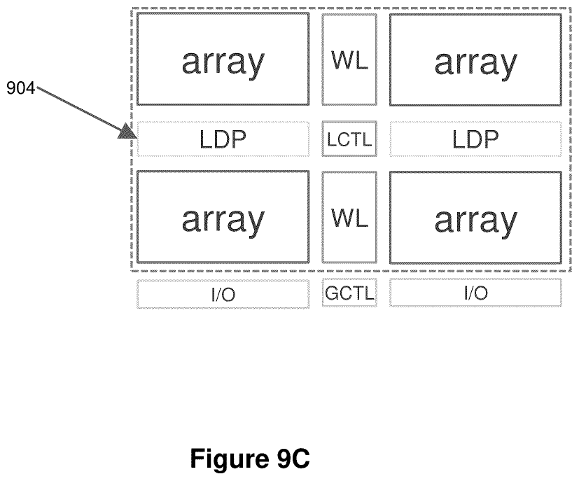

FIGS. 9A, 9B, and 9C illustrate SSB implementation in LDP 904 cell shown in FIG. 9C—Bitlines circuits, in accordance with various embodiments. Shown in FIGS. 8A, 8B, and 8C may be write and read muxes—bitlines supply may be VDD_LDP 902 shown in FIGS. 9A and 9B and the switch-able supply.

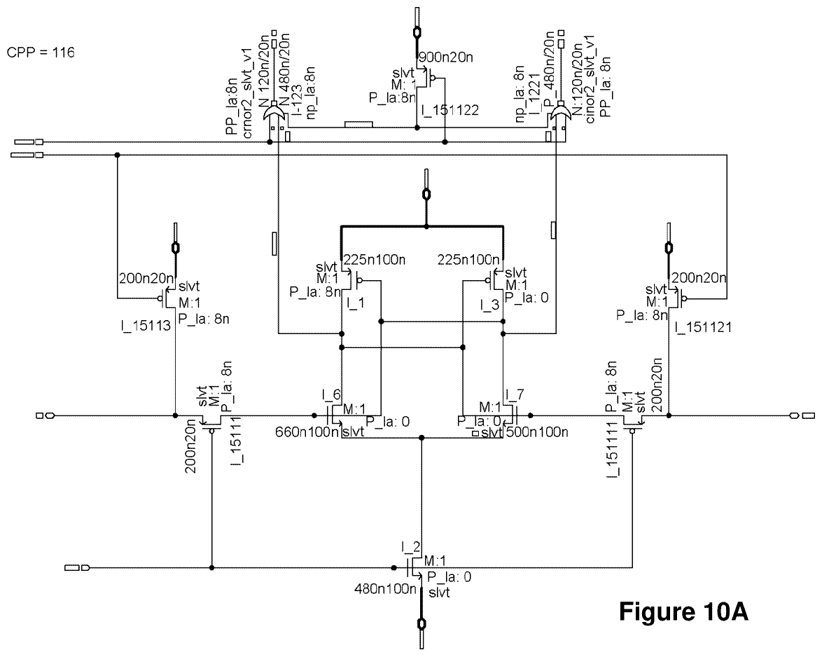

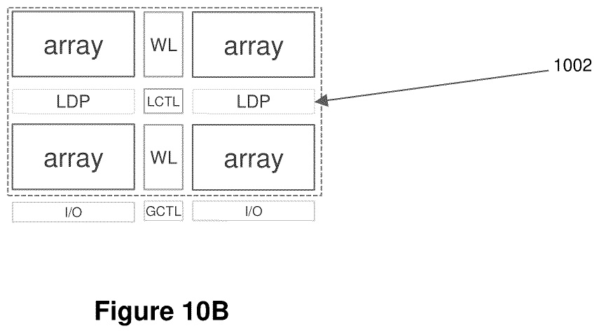

FIGS. 10A and 10B illustrate SSB implementation in LDP cell 1002 shown in FIG. 10B—Sense Amp, in accordance with various embodiments. Shown in FIGS. 10A and 10B may be the following:
Nor2 gates at the top may be coupled according to guidelines
Sense supplies may switch-able to facilitate avoidance of leakage path to the bitlines
The bottom enable NMOS, which may be coupled according to guidelines to GND_LDP, may be configured to function as the actual leakage reduction device

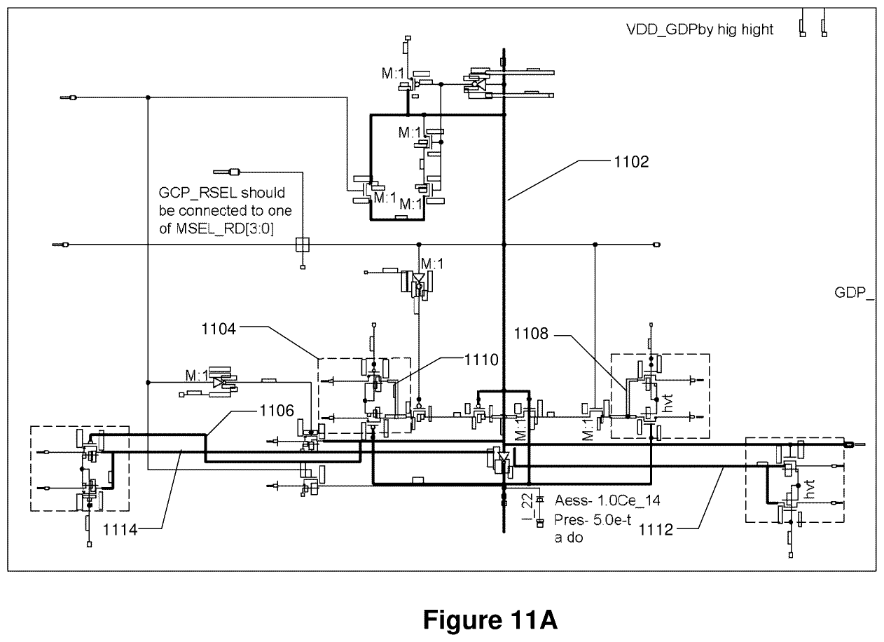

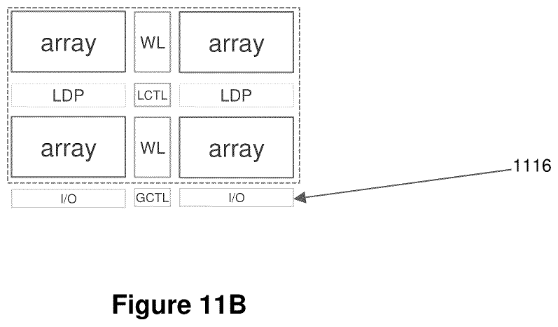

FIGS. 11A and 11B illustrate exception handling (3)—type B switches activated according to logic state, in accordance with various embodiments. Shown in FIGS. 10A and 10B may be the following:
When few signals are logically dependent upon each other in a one-to-one manner, Type B switch may be possible
Since the cost may be the area, the leakage savings may be improved and/or substantial
The schematic shown may be of GDP showing the i/o cell of the memory 1116 shown in

FIG. 11B, where the output driver may be seen
The functionality may be such that of RDATA 1102, where the yellow signal may be a tri state bus. Accordingly, in this schematic there may be the following:
   The keeper
   The mux stage
   The output inverter
The fragmented rectangles 1104 may surround type B switches, where each may have a separate control with substantially all controls being logically related
Each control may be for both, supply and ground switches. (e.g., signal 1106 shown)
The second control in each type B switch may be the “global” EN_GND or EN_VDD_N signals
The 1108, 1110, 1112, and 1114 may be supplies outputs from the type B switches, which may be utilized “safely” as supplies for the shown circuits.

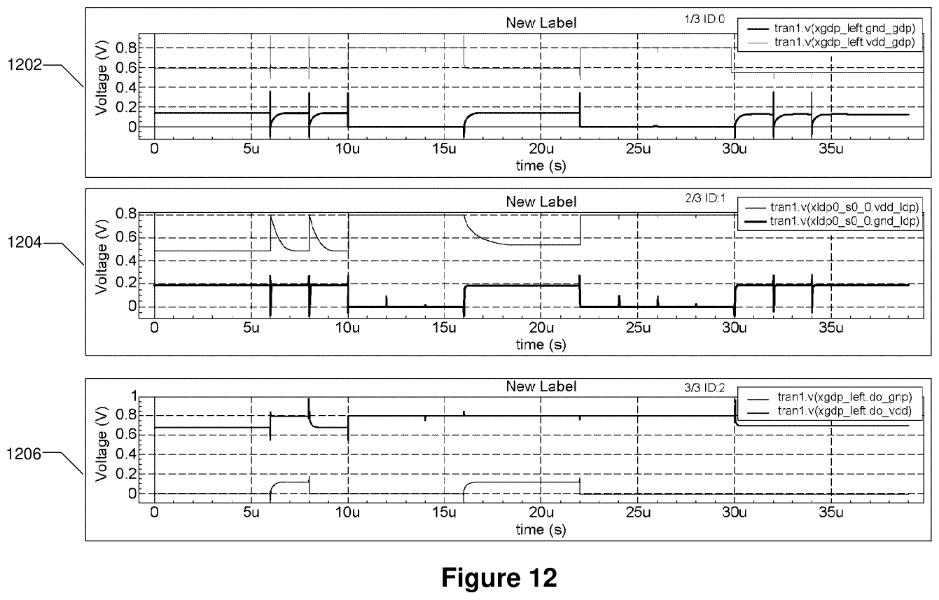

FIG. 12 illustrates some waveform signals received during the utilization of SSB implementation, in accordance with various embodiments. Shown in FIG. 11, a first signal 1202 may be a waveform output of operation of a switch-able supply and ground in GDP. A second signal 1204 may be a waveform output of operation of a switch-able supply and ground In LDP. A third signal 1206 may a waveform output of operation of conditionally switch-able supply and ground. Because of a logic dependance, the switching may be alternating between supply and ground.

As a result, the various embodiments disclosed may include at least some of the following:
Various control signals that behave as gated clocks have known logic state in standby, and accordingly, may be managed with type A switch (e.g., WL)
Address and WR_N inputs may be first latched to facilitate the state in the latch may be forced to a known state when SSB mode is active
   Type A may be utilized in these latches
Mux control signals in the data-path cells (LDP) may have one active signal out of four. A logic change may have been made such that in SSB mode substantially all are not active, which may result in substantially all of LDP inputs may be in a known state
Address decoders for WL selection may have been change such that in SSB mode, substantially none of the WLs may be selected
Since output state is not known in advance, the data output driver may be managed with type B switches
SSB control logic may not necessarily have a switch because of its role
(Array bitcells may have “normal” array source bias).

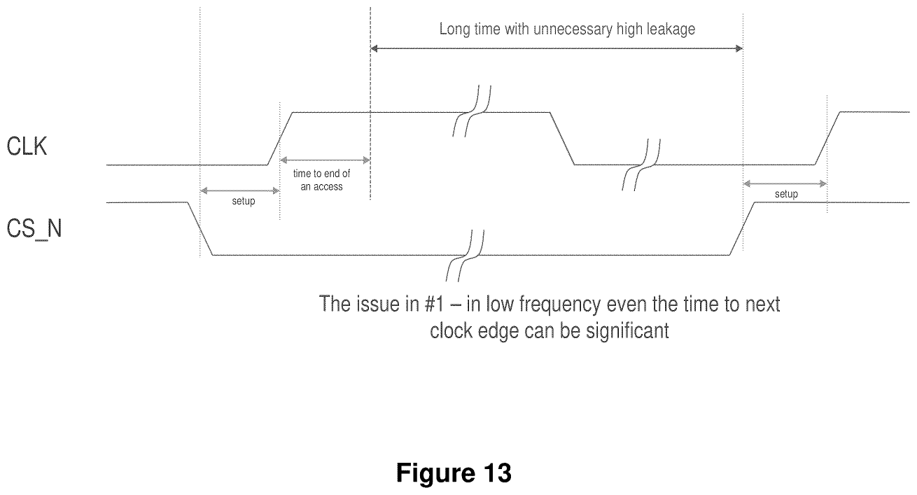

FIG. 13 illustrates at least some examples of logic conditions for entering Selective SB, in accordance with various embodiments. In FIG. 13, some examples of logic conditions for entering SSB may include the following:
CS_N change to “1” may automatically put the memory in SSB
   May not be efficient enough when the entire domain may be run at very low frequency
Automatic activation, where SSB may be turned off at clock rise and turned on at end of access
   This may require some delay at access start for switch-able supplies recovery, which may not be an issue if speed requirement relatively low/medium
Dedicated input
   May have similar characteristics as not being efficient enough when the entire domain may be run at very low frequency.

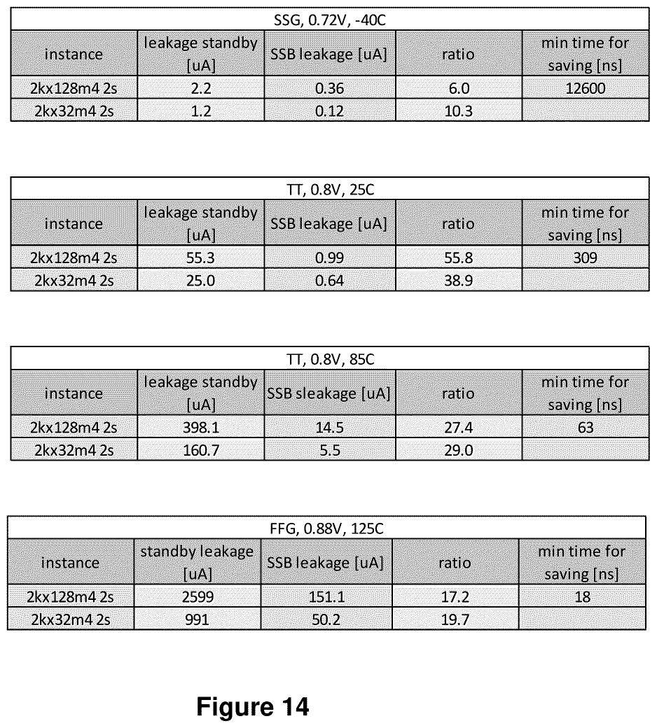

FIG. 14 illustrates some examples of benchmark results. In FIG. 14, the following may be shown:
SSB leakage may occur when array source bias is also active
Min time for saving may include minimum time period for actual energy savings, which may occur when the energy cost of transition may be considered
As shown, for SSG, 0.72V, −40 C corner, the gate leakage may become substantially significant, which may cause the gain being relatively smaller than other PVT's.

FIG. 14 illustrates exception handling—propagation path from shifted levels to “true 0/1” levels, in accordance with various embodiments. In FIG. 14, the following may be shown:
RDATA may be an exception by being a signal whose levels may be shifted to the levels of the SB supplies
DO, the memory data out port may remain driven to “true 0 ” or “true 1” levels having the usual driver strength
The solution may include adding the two transistors surrounded by a dashed green rectangle
The feedback of the DO signal may guarantee an open path to a non-switch-able supply
   Leakage may be substantially prevented
DO may be driven at normal strength.

1. A periphery of an instance of a memory circuit comprising:
a first inverter circuit having a first and a second transistor, one of the first or second transistor being in an off state;
a second inverter circuit having a third and fourth transistor, one of the third or fourth transistor being in an off state and the first and second inverter circuits being communicatively coupled with each other;
a power supply, the power supply being communicatively coupled with the one of the first or second transistor being in the off state;
a ground, the ground being communicatively coupled with the one of the third or fourth transistor being in the off state;
means for applying a bias potential from the power supply to the one of the first or second transistor being in the off state; and
means for providing a bias ground to the one of the third or fourth transistor being in the off state.

2. The periphery of claim 1 further comprising means for deactivating the bias potential.

3. The periphery of claim 2, wherein the means for deactivating the bias potential comprises bringing back the voltage to a supply utilizing a setup time prior to a clock.

4. The periphery of claim 1, wherein the memory comprises a static random access memory (SRAM).

5. The periphery of claim 1, wherein the memory comprises a dynamic random access memory (DRAM).

6. The periphery of claim 1, wherein the means for applying the bias potential comprises means for applying the bias potential to one or more pull-down devices.

7. A method for selective source bias in a memory peripheral, the method comprising:
determining a first transistor in a first inverter circuit being in an off state;
determining a second transistor in a second inverter circuit being in an off state, the first and second inverter being communicatively coupled to each other;
communicatively coupling the first transistor with a power supply;
communicatively coupling the second transistor with a ground;
applying a bias potential from the power supply to the first transistor; and
providing a bias ground second transistor.
